(19) United States
(12) Patent Application Publication
(10) Pub. No.: US 2004/0136153 A1
(43) Pub. Date: Jul. 15, 2004

(54) COMPLEX PERIPHERAL MODULE

(76) Inventors: Hsiao-Li Peng, Taipei Hsien (TW); Ying-Hua Huang, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/605,096

(22) Filed: Sep. 9, 2003

(30) Foreign Application Priority Data
Jan. 15, 2003 (TW) 092200719

(51) Int. Cl. G06F 1/16; H05K 5/00; H05K 7/00

(52) U.S. Cl. 361/683

(57) ABSTRACT

A complex peripheral module has a housing and a main board. The housing forms an assembly space having a standard height. The complex peripheral module further has a plurality of peripheral devices, a frame, and a signal transferring device. The frame has a containing chamber such that the peripheral devices are stacked and contained in the containing chamber. The frame is combined with the housing to be mounted in the assembly space. Signals are transmitted from the peripheral devices to the main board via the signal transferring device.

### BACKGROUND OF INVENTION

1. Field of the Invention

The present invention relates to a complex peripheral module, and more particularly, to a complex peripheral module applied to a computer apparatus having limited internal space such that a plurality of peripheral devices are combined with the computer apparatus.

2. Description of the Prior Art

Refer to FIG. 1 and FIG. 2. FIG. 1 is a schematic diagram of a conventional computer apparatus serving as a server. FIG. 2 is a schematic diagram of the server unit shown in FIG. 1. As shown in FIG. 1 and FIG. 2, the conventional industrial computer comprises a plurality of server units (also termed unit) 4. Each server unit 4 comprises a housing 41 and a main board 42 contained in the housing 41. The housing 41 further comprises an assembly space 43 for placing peripheral devices, such as a floppy disc 5. In view of limited space, the size of each server unit 4 is strictly constrained wherein the height is merely 40 mm to 44 mm. Therefore only one standard peripheral device, e.g. a floppy disc, a hard disc, a CD-ROM, or a small display 6 for displaying operation information of the server unit 4, is able to be positioned in the server unit 4. Once more than one peripheral device needs to be installed in the server unit 4, such as the floppy disc 5 and the small display 6 shown in FIG. 2, they can be only arranged in parallel in the housing 41 of the server unit 4. However, this kind of arrangement occupies too much space in the server unit 4, consequently the remaining space for the main board 42 is reduced.

Furthermore, since smaller electronic products are increasingly required, more slim peripheral devices, such as a slim floppy discs are becoming available. Accordingly, similar peripheral devices, such as a slim hard disc or a slim CD-ROM, are also proposed. Although slim peripheral devices are slimmer than the peripheral device with standard height, related server units having suitable structure for assembling slim peripheral devices do not exit thus far. Slim peripheral devices have to be arranged in parallel in the conventional server unit. Since the available space for the main board is not increased, it is ineffective to adapt the slim peripheral devices.

### SUMMARY OF INVENTION

It is therefore a primary object of the claimed invention to provide a complex peripheral module for integrating a plurality of slim peripheral devices into the standard assembly space of a computer apparatus.

According to the claimed invention, a complex peripheral module applied to a computer apparatus is disclosed. The computer apparatus comprises a housing and a main board contained in the housing. The housing has an assembly space with a standard height. The peripheral module comprises a plurality of peripheral devices, a frame, and a signal transferring device, wherein each peripheral device has a thickness smaller than the height of the assembly space. The frame has a plurality of side walls connected to each other, the plurality of side walls forms a containing chamber matching the assembly space such that the plurality of peripheral devices are contained in the containing chamber. The frame and the housing are assembled and fixed in the assembly space. The signal transferring device is mounted in the frame for transferring signals from the peripheral devices to the main board. The plurality of peripheral devices are simultaneously positioned in the assembly space by the frame and the signal transferring device.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 is a perspective diagram of a conventional computer apparatus having a plurality of server units.

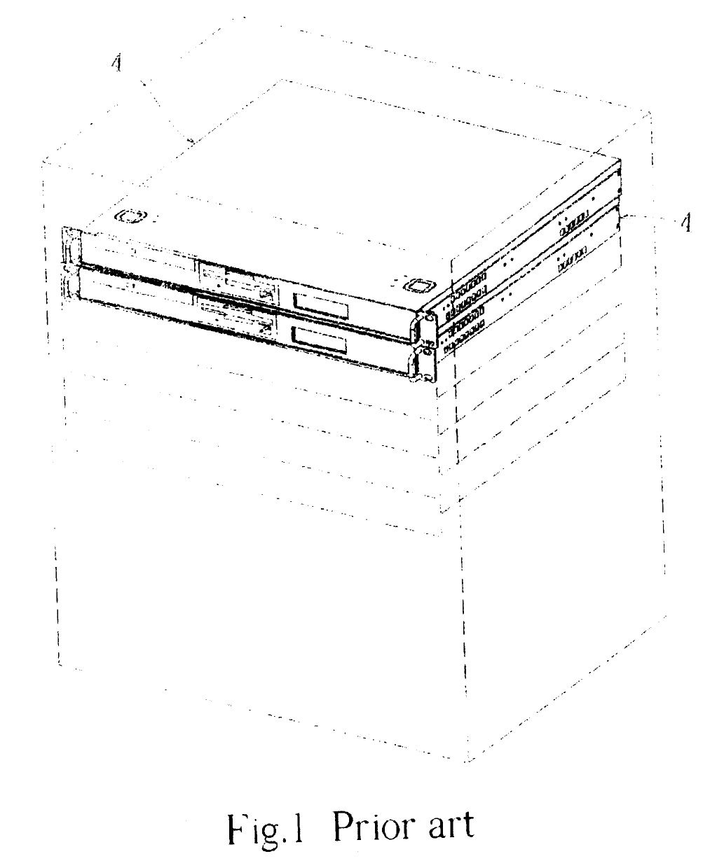

FIG. 2 is a perspective diagram of the server unit shown in FIG. 1.

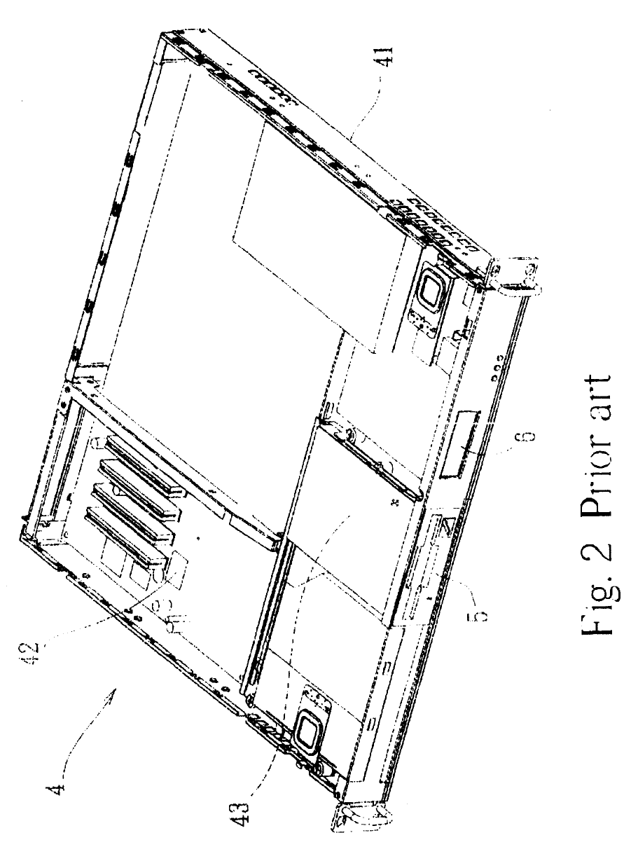

FIG. 3 is a perspective diagram illustrating the complex peripheral module of a preferred embodiment of the present invention applied to a server unit of a computer apparatus.

FIG. 4 is an exploded view of the complex peripheral module shown in FIG. 3.

FIG. 5 is a perspective diagram of a fastener of the present invention.

FIG. 6 is a schematic diagram illustrating operations of the fastener.

FIG. 7 is a schematic diagram of the complex peripheral module applied to a personal computer.

### DETAILED DESCRIPTION

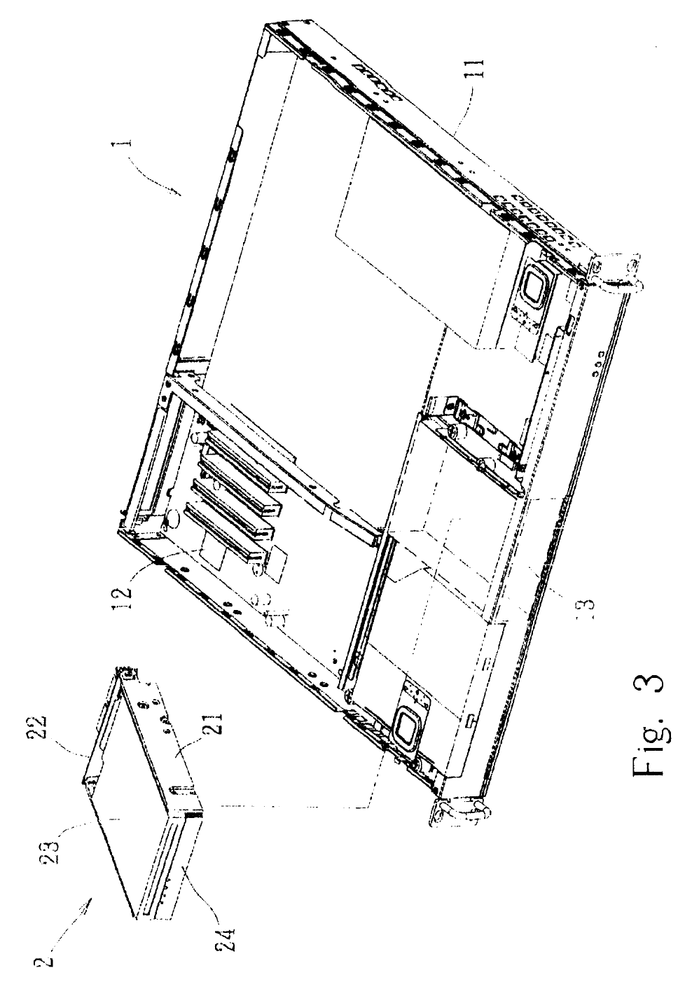

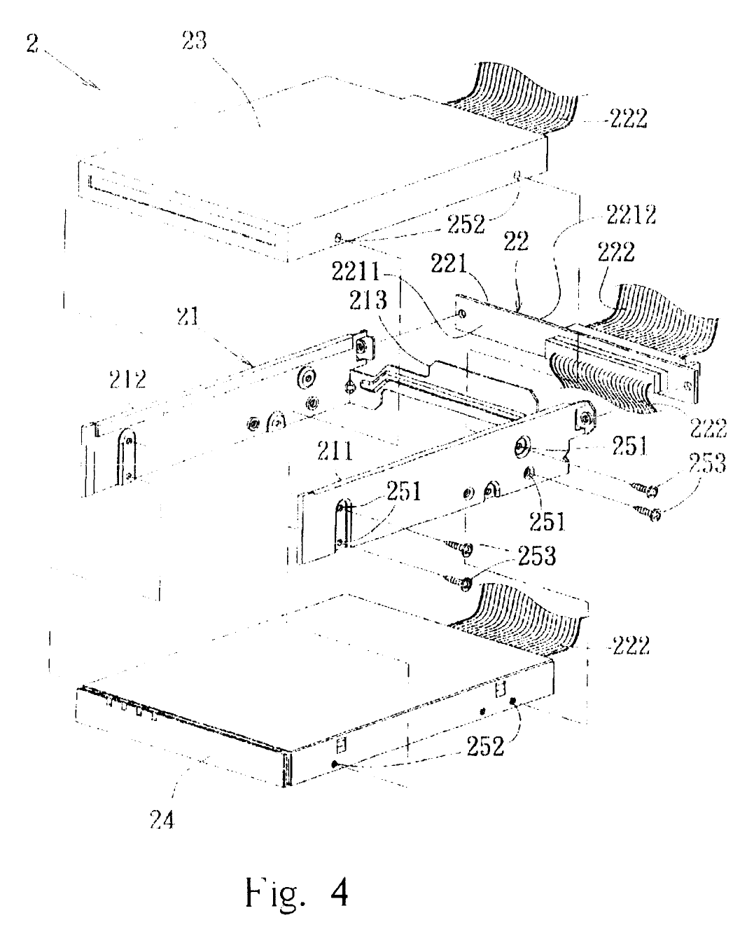

Refer to FIG. 3 and FIG. 4. FIG. 3 is a perspective diagram illustrating the complex peripheral module of a preferred embodiment of the present invention applied to a server unit of a computer apparatus. FIG. 4 is an exploded view of the complex peripheral module shown in FIG. 3. The complex peripheral module of the present invention is applied to a computer apparatus. In the preferred embodiment of the present invention, an industrial computer, which functions as a server, is selected as an example for illustrating the present invention. Since the server has a plurality of server units (known as units), a server unit 1, on behalf of the computer apparatus, is used. The server unit 1 comprises a housing 11 and a main board 12 contained in the housing 11. The housing 11 comprises an assembly space 13 having a standard height (40 mm to 44 mm).

The complex peripheral module 2 comprises a plurality of peripheral devices, a frame 21, and a signal transferring device 22. In the preferred embodiment of the present invention, the peripheral devices are a slim floppy disc 23 and an interface display 24 for displaying operation information of the server unit 1. The thickness of the slim floppy disc 26 and the thickness of the interface display are both smaller than the standard height of the assembly space 13 (approximately half of the standard height).

The frame 21 comprises a first side wall 211, a second side wall 212 facing to the first side wall 211, and a third side wall 213 connecting the first side wall 211 and the second side wall 212. Therefore, the side walls form a U-shape frame such that a containing chamber 214, which matches the assembly space 13, is defined.

The signal transferring device 22 comprises a circuit board 221 and a plurality of flexible flat cables 222. The circuit board 221 is rectangular, connected to the first side wall 211 at one end, and connected to the second side wall 212 at another end. The circuit board 221 comprises a transferring circuit (not shown) such that the plurality of flexible flat cables are coupled to the circuit board 221 through both faces. The flexible flat cables, which are coupled to a first face 2211 of the circuit board 221 at one end, are connected to the slim floppy disc 23 and the interface display 24 at another end. The flexible flat cables, which are coupled to a second face 2212 of the circuit board 221 at one end, are connected to the main board 12 at another end. Therefore, signals are transmitted from the slim floppy disc 23 and the interface display 24 to the main board 12 via the signal transferring device 22.

In the preferred embodiment, the slim floppy disc 23 and the interface display 24 are stacked to combine with the frame 21 by a connecting component. The connecting component comprises a plurality of openings 251 positioned on the first side wall 211 and the second side wall 212, a plurality of threaded holes, which correspond to the openings 251, positioned on the slim floppy disc 23 and the interface display 24, and a plurality of screws 253 that pass through the openings 251 and are screwed into the threaded holes 252 such that the slim floppy disc 23 and the interface display 24 are fixed in the containing chamber 214 of the frame 21.

In addition, the flexible flat cables 222, which are coupled to the first face 2211 of the circuit board 221, are electrically connected to the slim floppy disc 23 and the interface display 24. Thus, the peripheral devices, the frame 21, and the signal transferring device 22 form a module. When this module is installed into the assembly space 13 of the server unit 1, the two peripheral devices can both be used. This saves a lot of space and provides more space for the main board 12. This allows the main board 12 to contain more elements.

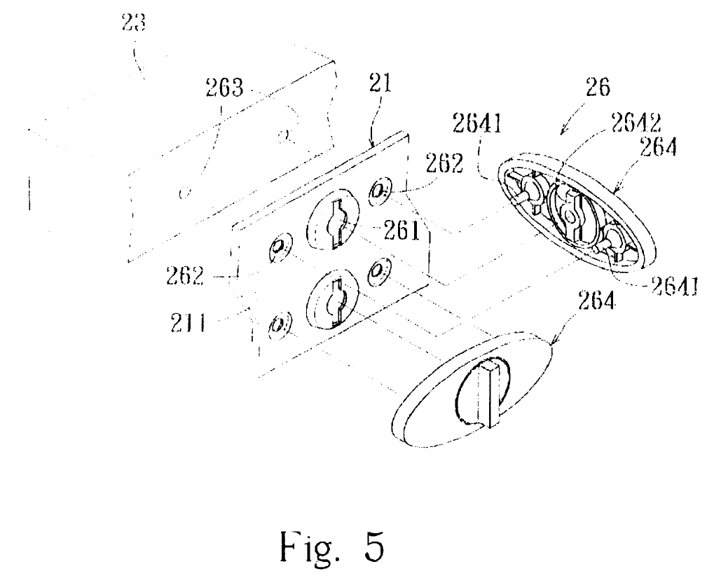

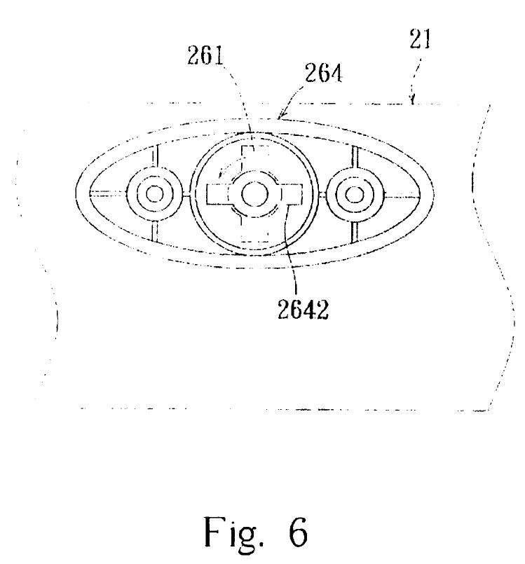

Refer to FIG. 5 and FIG. 6. FIG. 5 and FIG. 6 illustrate another embodiment of the present invention. Another connecting component 26 is employed in this embodiment. The connecting component 26 comprises a non-circular hole 261 positioned on the first side wall 211 or the second side wall 212, and two orientation holes 262 positioned on both sides of the non-circular hole 261. The connecting component 26 further comprises two holes 263 on a wall of the slim floppy disc 23 or the interface display 24, and a fastener 264. The fastener 264 has protrusions 2641 and a rotatable bolt 2642. The protrusions 2641 pass through the orientation holes 262 and fit into the holes 263 for fixing the position of the slim floppy disc 23 or the interface display 24. The bolt 2642 has an identical shape as the non-circular hole 261 at one end such that the bolt 2642 passes through the non-circular hole 261. When the bolt 2642 is inserted into the non-circular hole 261 and rotated by an angle, the slim floppy disc 23 or the interface display 24 becomes fixed in the containing chamber 214 of the frame 21. It is worth noting that any amount of orientation holes 262 can be used.

When the slim floppy disc 23 or the interface display 24 needs to be disassembled from the frame 21, the bolt 2642 is rotated to its original angle and the fastener 264 is removed allowing the slim floppy disc 23 or the interface display 24 to be taken out.

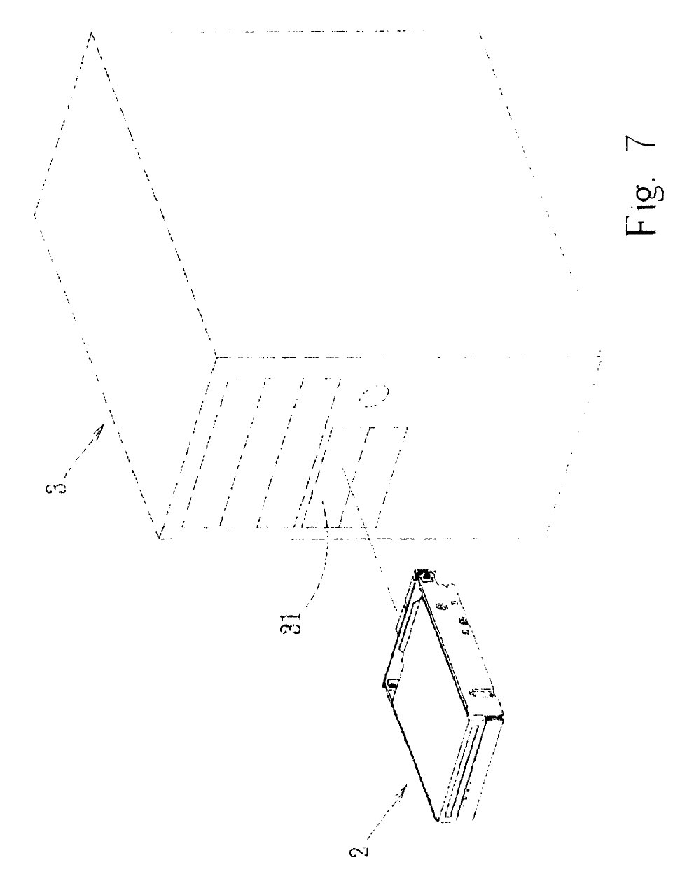

Refer to FIG. 7, which is a schematic diagram of the complex peripheral module applied to a personal computer. As shown in FIG. 7, the complex peripheral module 2 is suitable for a personal computer 3. The complex peripheral module 2 can be installed into a single assembly space 31 of the personal computer so as to reduce the space used by the peripheral devices.

In conclusion, the complex peripheral module integrates a plurality of slim peripheral devices into a standard assembly space, such that the space of a computer apparatus is fully employed. In addition, it is worth noting that the peripheral devices are not limited to a slim floppy disc or an interface display, other peripheral devices such as a slim hard disc, a CD-ROM, etc are also suitable for the present invention.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A complex peripheral module applied to a computer apparatus, the computer apparatus comprising a housing, and a main board positioned inside the housing, the housing forming an assembly space having a standard height, the complex peripheral module comprising:
a plurality of peripheral devices, each peripheral device having a thickness less than the height of the assembly space;
a frame having a plurality of side walls connecting to each other, the plurality of side walls defining a containing chamber matching the assembly space such that the plurality of peripheral devices are contained in the containing chamber, and the frame and the housing being assembled and fixed in the assembly space; and
a signal transferring device mounted in the frame for transferring signals from the peripheral devices to the main board;
wherein the plurality of peripheral devices are simultaneously positioned in the assembly space by the frame and the signal transferring device.

2. The complex peripheral module of claim 1 further comprising a plurality of connecting components such that the peripheral devices are mounted on the side walls.

3. The complex peripheral module of claim 2 wherein each connecting component comprises an opening on the side wall of the frame, a threaded hole on a wall of the peripheral device, and a screw passing through the opening and screwed into the threaded hole so that the peripheral device and the frame are fixed together.

4. The complex peripheral module of claim 2 wherein each connecting component comprises:
an orientation hole and a non-circular hole in the side wall of the frame;
a hole on a wall of the peripheral device corresponding to the orientation hole; and
a fastener having a protrusion and a rotatable bolt;
wherein the protrusion fits into the orientation hole of the frame and the hole of the peripheral device, and the bolt fits into the non-circular hole and can be rotated such that the peripheral device and the frame are assembled.

5. The complex peripheral module of claim 1 wherein the signal transferring device further comprises a circuit board with a transferring circuit and a plurality of flexible flat cables electrically connected to the circuit board, the flexible flat cables being electrically connected to the peripheral devices and the main board at another end.

6. The complex peripheral module of claim 1 wherein the peripheral devices comprises a floppy disc and an interface display.
